(19) United States
(12) Patent Application Publication
(10) Pub. No.: US 2026/0214909 A1
(43) Pub. Date: Jul. 23, 2026

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: CHIA YU LING, HSINCHU CITY (TW); MING-YEN CHUANG, HSINCHU CITY (TW); KATHERINE H. CHIANG, NEW TAIPEI CITY (TW)

(21) Appl. No.: 19/034,610

(22) Filed: Jan. 23, 2025

(51) Int. Cl. H10B 53/30

(52) U.S. Cl. CPC H10B 53/30

(57) ABSTRACT

A semiconductor device includes a capacitor and a transistor disposed over and coupled to the capacitor. The capacitor includes a bottom electrode, a top electrode, and a ferroelectric material layer between the bottom electrode and the top electrode. The ferroelectric material layer covers sidewalls and a top surface of the bottom electrode. The transistor is coupled to the top electrode of the capacitor. The transistor includes a gate, a semiconductor layer wrapped around the gate, and a dielectric layer between the gate and the semiconductor layer.

### BACKGROUND

Ferroelectric random-access memory (FeRAM) is a candidate for the next generation of non-volatile memory in modern electronic devices. FeRAM has a relatively simple structure and is compatible with complementary metal-oxide-semiconductor (CMOS) logic fabrication processes. FeRAM offers advantages such as non-volatility, low power consumption, short programming time, and high read/write endurance. As the semiconductor industry continues to increase density of electronic components in integrated circuits, FeRAM is being integrated within interconnect levels stacked above a semiconductor substrate. With its potential for high component density and compatibility with advanced semiconductor technology, FeRAM is drawing increasing attention for its potential in future electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1D are schematic drawings illustrating a semiconductor memory structure in accordance with aspects of the present disclosure in one or more embodiments, wherein FIG. 1A is a perspective view of the semiconductor memory structure, FIG. 1B is a cross-sectional view taken along line I-I′ of FIG. 1A, FIG. 1C is a planar view of plural semiconductor memory structures, and FIG. 1D is a cross-sectional view taken along line II-II′ of FIG. 1A.

FIG. 2 is a cross-sectional view of a semiconductor structure including at least a FeRAM cell and a portion of a back-end-of-line (BEOL) interconnect structure in accordance with aspects of the present disclosure in one or more embodiments.

FIGS. 3A and 3B are circuit diagrams of a semiconductor memory structure in accordance with aspects of the present disclosure in one or more embodiments.

FIG. 4 is a flowchart representing a method for forming a semiconductor memory structure according to aspects of the present disclosure.

FIGS. 5A, 6A, 7A, 8A, 9A, 10A, 11A, 12A, 13A and 14A are cross-sectional views illustrating a semiconductor memory structure at various fabrication stages in a first plane in accordance with aspects of one or more embodiments of the present disclosure.

FIGS. 5B, 6B, 7B, 8B, 9B, 10B, 11B, 12B, 13B and 14B are another cross-sectional views illustrating the semiconductor memory structure at various fabrication stages in a second plane in accordance with aspects of one or more embodiments of the present disclosure.

FIGS. 15A and 16A are cross-sectional views illustrating a semiconductor memory structure at a fabrication stage subsequent to that shown in FIG. 11A in accordance with aspects of one or more embodiments of the present disclosure.

FIGS. 15B and 16B are cross-sectional views illustrating the semiconductor memory structure at a fabrication stage subsequent to that shown in FIG. 11B in accordance with aspects of one or more embodiments of the present disclosure.

FIGS. 17A, 18A, 19A, 20A and 21A are cross-sectional views illustrating a semiconductor memory structure at various fabrication stages subsequent to that shown in FIG. 14A or FIG. 16A in accordance with aspects of one or more embodiments of the present disclosure.

FIGS. 17B, 18B, 19B, 20B and 21B are cross-sectional views illustrating the semiconductor memory structure at various fabrication stages subsequent to that shown in FIG. 14B or FIG. 16B in accordance with aspects of one or more embodiments of the present disclosure.

FIG. 22 is a cross-sectional view illustrating a semiconductor structure in accordance with aspects of one or more embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

A one-transistor one-capacitor (1T1C) memory cell is a type of memory that includes a capacitor and a transistor. The capacitor stores charge, representing an individual bit of data, and the transistor allows for read and write operations to access the capacitor. This simple structure enables high memory density, leading to a high memory capacity and a low cost per bit. The 1T1C memory cells are used with dynamic random-access memory (DRAM), or FeRAM. FeRAM memory cells include a transistor and a ferroelectric capacitor structure, which can store data based on the alignment of atoms within the ferroelectric structure. FeRAM comes in different types, including 1T1C cell structured FeRAM, metal-ferroelectric-insulator-semiconductor field-effect transistor (MFIS-FET or FeFET), and metal-ferroelectric-metal-insulator-semiconductor field-effect transistor (MFMIS-FET), each with its own unique advantages. However, it is found that a planar 1T1C FeRAM occupies large area. Further, it is difficult to scale down a device size of the 1T1C FeRAM having the planar configuration.

The present disclosure therefore provides a semiconductor memory structure and a method for forming the same. In some embodiments, the semiconductor memory structure is a non-planar 1T1C FeRAM formed in a back-end-of-line (BEOL) interconnect structure. The 1T1C FeRAM helps to provide lower operation noise of unselected bit line (BL) and better data retention. The non-planar 1T1C FeRAM is 3D stackable; therefore, it helps to increase device density. The non-planar 1T1C FeRAM integrated in the BEOL interconnect structure is a BEOL junction-less device. Further, the method for forming the non-planar 1T1C FeRAM integrated in a BEOL interconnect structure is a logic-compatible process.

While the present disclosure discusses aspects of methods of forming a FeRAM cell in the context of a BEOL process or middle end of line (MEOL) process performed after, e.g., a FinFET formation process, other embodiments may utilize aspects of this disclosure with other semiconductor fabrication processes.

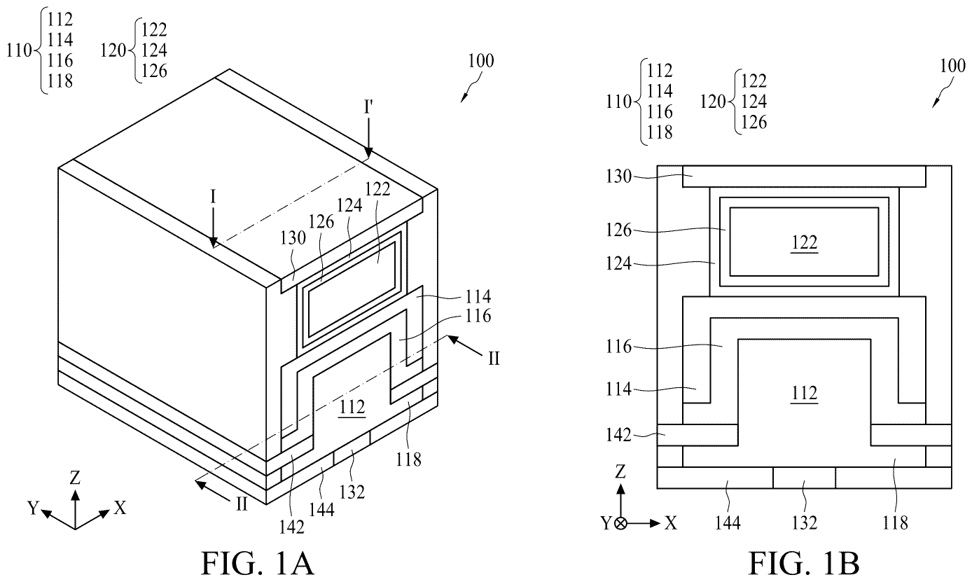

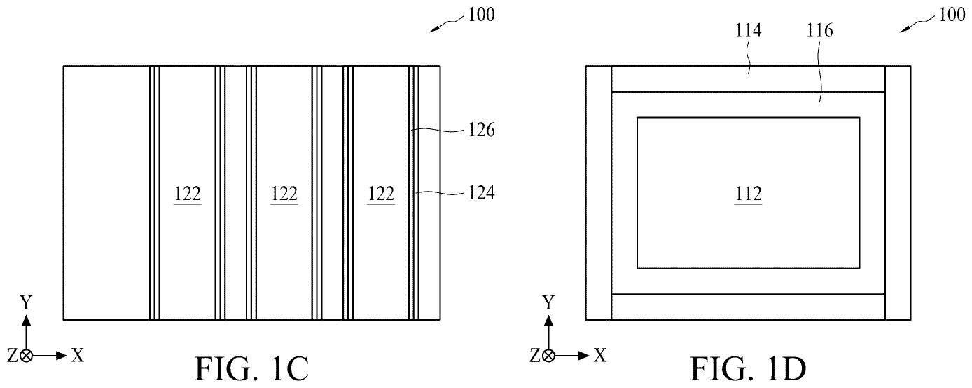

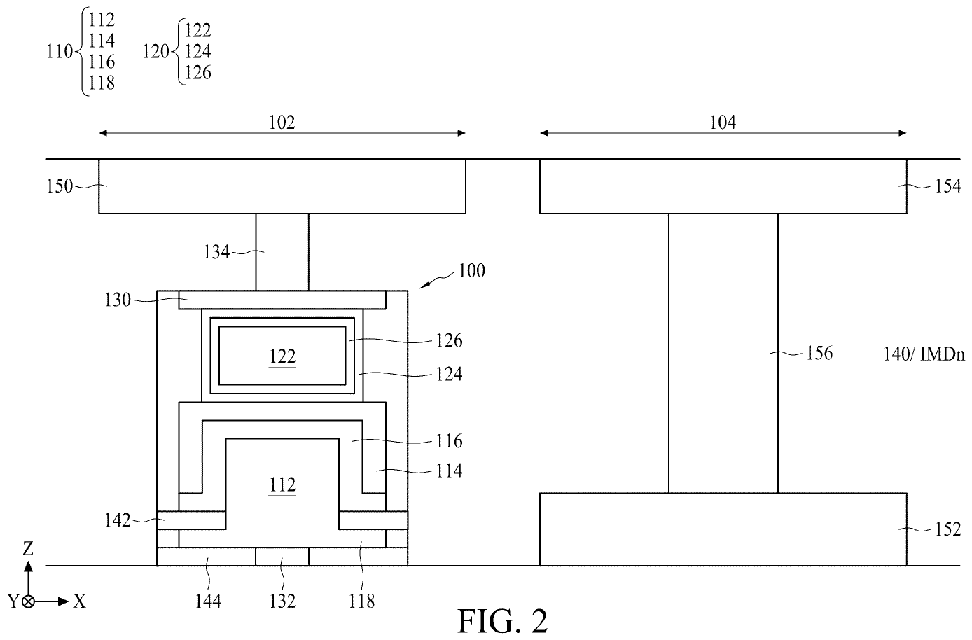

Please refer to FIGS. 1A to 1D and 2, wherein FIG. 1A is a perspective view of a semiconductor memory structure in accordance with aspects of the present disclosure in one or more embodiments, FIG. 1B is a cross-sectional view taken along line I-I′ in an X-Z plane of FIG. 1A, FIG. 1C is a planar view of plural semiconductor memory structures, and FIG. 1D is a cross-sectional view taken along line II-II′ in another X-Y plane of FIG. 1A. FIG. 2 is a schematic drawing illustrating a semiconductor structure including the semiconductor memory structure in accordance with aspects of the present disclosure in one or more embodiments.

In some embodiments, the semiconductor memory structure 100 may be formed over a substrate (not shown). In some embodiments, the substrate (not shown) may be any type of semiconductor body (including, for example, silicon (Si), silicon germanium (SiGe), silicon-on-insulator (SOI), or like), such as a semiconductor wafer and/or one or more dies on a wafer, as well as any other type of semiconductor and/or epitaxial layers, suitable for such application.

In some embodiments, the substrate can include FEOL devices and can be a portion of an IC chip, a system-on-chip (SoC), or a portion of an SoC. In some embodiments, the substrate can be a substrate accommodating FEOL devices such as microprocessors, memories, and/or other IC devices. In some embodiments, the substrate can include various passive and active microelectronic devices, such as resistors, capacitors, inductors, diodes, p-type field-effect transistors (PFETs), n-type field-effect transistors (NFETs), metal-oxide semiconductor field effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, other suitable components, or combinations thereof. The transistors may be planar transistors or multi-gate transistors, such as fin-type FETs (FinFETs).

In some embodiments, a layer of a MEOL interconnect structure (not shown) can be formed over the substrate. The layer of the MEOL interconnect structure includes a plurality of connecting vias (not shown) disposed in an inter-layer dielectric (ILD) layer (not shown). The connecting vias are coupled to the FEOL devices. In some embodiments, the connecting vias can include a via-to-gate (VG), which generally refers to a contact to a gate structure. In other embodiments, the connecting via can include a via-to-drain (VD), which generally refers to a contact to a source/drain region. Accordingly, the FEOL devices can be electrically connected to a BEOL interconnect structure through the layer of the MEOL interconnect structure.

In some embodiments, a BEOL interconnect structure (shown in FIG. 2) is formed over the substrate and is electrically connected to the FEOL devices over the substrate. In some embodiments, the BEOL interconnect structure can include a plurality of metallization layers referred to, in ascending order, as the zeroth metallization layer M0, the first metallization layer M1, the Nth metallization layer Mn, and the (Mn+1)th metallization layer, and a plurality of connecting vias referred to as the zeroth via V0, the first via V1, and the Nth via Vn, wherein n is a positive integer. The Nth metallization layer Mn and the (Mn+1)th metallization layer Mn+1 can be electrically connected by the Nth via Vn. Further, the metallization layers Mn and Mn+1 and the connecting vias Vn can be formed in an inter-metal dielectric layer IMDn, which provides mechanical support and electrical isolation for the metallization layers Mn and Mn+1, and the connecting via Vn. In some embodiments, the semiconductor memory structure 100 is disposed in the BEOL interconnect structure.

The semiconductor memory structure 100 includes a capacitor 110 and a transistor 120 electrically connected to each other. Further, the capacitor 110 and the transistor 120 may be stacked in a first direction (i.e., a Z direction), with the transistor 120 disposed over the capacitor 110, as shown in FIGS. 1A and 1B. In some embodiments, the capacitor 110 includes a bottom electrode 112, a top electrode 114 over the bottom electrode 112, and a ferroelectric material layer 116 between the bottom electrode 112 and the top electrode 114. Further, the ferroelectric material layer 116 covers sidewalls and a top surface of the bottom electrode 112, as shown in FIGS. 1A, 1B and 1D. In such embodiments, the ferroelectric material layer 116 may have a U-shaped (or an inverted U-shaped) configuration in a cross-sectional view (i.e., in an X-Z plane cross-sectional view), as shown in FIG. 1B. In some embodiments, the top electrode 114 covers sidewalls and a top surface of the ferroelectric material layer 116. In such embodiments, the top electrode 114 may have a U-shaped (or an inverted U-shaped) configuration in a cross-sectional view (i.e., in the X-Z plane cross-sectional view), as shown in FIG. 1B.

In some embodiments, each of the bottom electrode 112, the top electrode 114 and the ferroelectric material layer 116 may extend in a second direction (i.e., a Y direction). In some embodiments, the bottom electrode 112, the ferroelectric material layer 116 and the top electrode 114 may be stacked in the first direction (i.e., the Z direction). In some embodiments, the capacitor 110 further includes a storage node 118 disposed under and coupled to the bottom electrode 112.

The bottom electrode 112 may include metal materials such as tungsten (W), ruthenium (Ru), copper (Cu), and combinations thereof, but the disclosure is not limited thereto. The top electrode 114 may include metal materials such as W, Ru, Cu and combinations thereof, but the disclosure is not limited thereto. In some embodiments, the top electrode 114 and the bottom electrode 112 include a same material, but the disclosure is not limited thereto. The storage node 118 may include metal materials such as W, Ru, Cu and combinations thereof, but the disclosure is not limited thereto. In some embodiments, the storage node 118 and the bottom electrode 112 include a same material, but the disclosure is not limited thereto.

In some embodiments, the ferroelectric material layer 116 includes a material having dielectric crystals which exhibit an electric polarization having a direction that can be controlled by an electric field. For example, in some embodiments, the ferroelectric material layer 116 may include hafnium oxide (HfO₂), hafnium zinc oxide (HfZnO₂), zinc oxide (ZnO), Zr-doped HfO₂, Al-doped HfO₂, Sc-doped TiN, potassium nitrate (KNO₃), bismuth ferrite (BiFeO₃), bismuth manganite (BiMnO₃), yttrium manganite (YMnO₃), terbium manganite (TbMnO₃), lead zirconate titanate (also known as lead zirconium titanate) (Pb[ZrₓTi₁₋ₓ]O₃ (0≤x≤1), Pb(Zr,Ti)O₃, PZT), Pb(Sc_{0.5}Ta_{0.5})O₃, Pb(Sc_{0.5}Nb_{0.5})O₃, Pb(Mg_{1/3}Nb_{2/3})O₃, Pb(Zn_{1/3}Nb_{2/3})O₃, lithium tantalate (LiTaO₃), lithium niobate (LiNbO₃), strontium bismuth tantalate, (Sr_{0.8}Bi₂Ta_{2.2}O₉ SBT), strontium bismuth niobium oxide (SrBi₂Nb₂O₉, SBN), lead titanate (PbTiO₃), barium titanate (BaTiO₃), lithium titanate (LiTiO₃), lithium niobate (LiNbO₃), BeFeO₃, potassium niobate (KNbO₃), potassium tantalate (KTaO₃), calcium titanate (CaTiO₃), gadolinium orthoferrite (GdFeO3), dysprosium scandate (DyScO3), bismuth tungstate (Bi₂WO₆), bismuth titanate (Bi₄Ti₃O₁₂, BTO), Mn₃TeO₆, lead germanate (Pb₅Ge₃O₁₁), gadolinium molybdate (Gd₂(MoO₄)₃), R₃Sb₅O₁₂ (R═Pr, Nd, Sm, Eu, Gd, Yb), lithium-sodium tetragermanate LiNaGe₄O₉, LNG), barium aluminate (BaAl₂O₄), lithium heptagermanate (Li₂Ge₇O₁₅, LGO), yttrium manganite (YMnO₃), samarium hexaboride (SmB₆), barium bismuthate (BaBiO₃, BBO), lutetium ferrite (LuFe₂O₄), yttrium ferrite (YFe₂O₄), iron borate (Fe₂BO₄), lanthanum strontium nickelate (La_{1.5}Sr_{0.5}NiO₄), or the like.

The transistor 120 includes a gate 122, a semiconductor layer 124 wrapped around the gate 122, and a dielectric layer 126 between the semiconductor layer 124 and the gate 122. In some embodiments, the gate 122 may be referred to as a portion of a word line (WL), but the disclosure is not limited thereto. In some embodiments, the gate 122 includes metal materials or metallization materials such as W, Ru, titanium nitride (TiN), or combinations thereof, but the disclosure is not limited thereto. In some embodiments, the semiconductor layer 124 may include an oxide semiconductor layer. In some embodiments, the semiconductor layer 124 may include indium gallium zinc oxide (IGZO), or a similar conductive oxide semiconductor material such as indium tin oxide (ITO), indium tungsten oxide (IWO), indium zinc oxide (IZO), zinc tin oxide (ZTO) or a combinations thereof, but the disclosure is not limited thereto. In some embodiments, the dielectric layer 126 may include a high-k dielectric material. In some embodiments, the dielectric layer 126 may include zirconium oxide, hafnium oxide, aluminum oxide, titanium oxide, tantalum oxide, Gd₂O₃, BaTiO₃, LaO₂, Y₂O₃, HfZrO, HfLaO, HfTaO, HfTiO, or combinations thereof. In some embodiments, the dielectric layer 126 includes one or more materials selected from aluminum oxide, hafnium oxide, tantalum oxide and zirconium oxide.

Referring to FIGS. 1A and 1B, in some embodiments, each of the semiconductor layer 124 and the dielectric layer 126 has an O-shaped configuration in a cross-sectional view (i.e., in the X-Z plane cross-sectional view). Referring to FIGS. 1A and 1B, in some embodiments, the semiconductor layer 124 of the transistor 120 is coupled to the top electrode 114 of the capacitor 110. In some embodiments, the semiconductor layer 124 is in contact with the top electrode 114. In some embodiments, a bottom of the semiconductor layer 124 and a top of the semiconductor layer 124 are referred to as a source/drain region of the transistor 120. In such embodiments, portions of the semiconductor layer 124 between the top and the bottom are referred to as a channel region of the transistor 120.

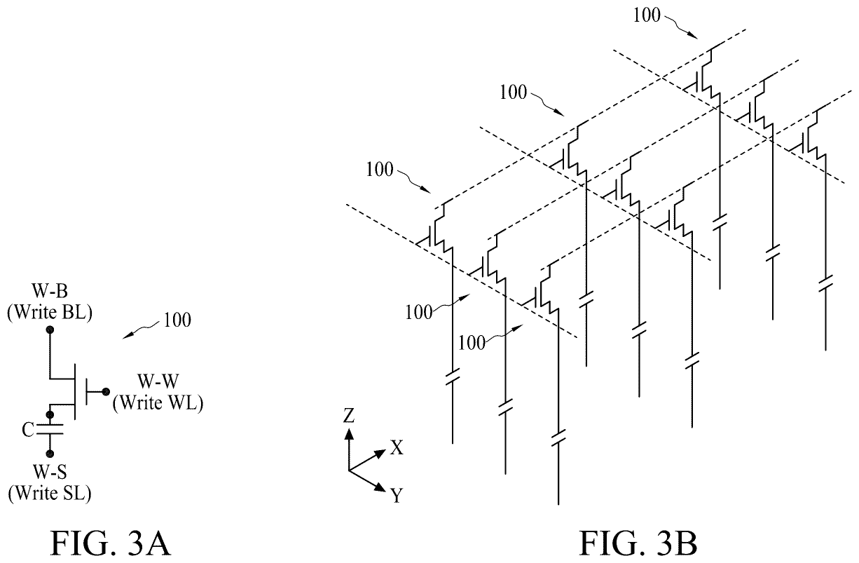

Accordingly, the semiconductor memory structure 100 including one capacitor 110 and one transistor 120 is referred to as a non-planar 1T1C FeRAM memory cell, as shown in FIGS. 1A and 3A, wherein FIG. 3A is a circuit diagram of the semiconductor memory structure 100 in accordance with aspects of the present disclosure in one or more embodiments. In some embodiments, the semiconductor memory structure 100 may be repeatedly or periodically arranged in a third direction (i.e., an X direction), as shown in FIGS. 1C and 3B, wherein FIG. 3B is a circuit diagram of semiconductor memory structures in accordance with aspects of the present disclosure in one or more embodiments. In some embodiments, the semiconductor memory structure 100 may be repeatedly or periodically arranged in the second and third directions (i.e., the Y direction and the X direction) to form an array. For example, the semiconductor structure 100 as shown in FIG. 1A can be repeatedly arranged in the third direction. Thus, the gates 122, the dielectric layer 126 and the semiconductor layers 124 of the transistors 120 of those repeatedly-arranged semiconductor structures 100 are also repeated arranged as shown in FIG. 1C, which is taken along the X-Y plane. It is concluded that a device density can be increased by the semiconductor memory structures 100 having the non-planar configuration.

In some embodiments, the semiconductor memory structure 100 further includes a conductive layer 130 disposed over and coupled to the top of the semiconductor layer 124 of the transistor 120. In some embodiments, the conductive layer 130 may be referred to as a bit line (BL).

Additionally, in some embodiments, the semiconductor memory structure 100 further includes an insulating layer 142 disposed between the ferroelectric material layer 116 and the storage node 118, and an insulating layer 144 disposed under the storage node 118. In such embodiments, a portion of a top surface of the storage node 118 is in contact with the insulating layer 142, and a portion of a bottom surface of the storage node 118 in in contact with the insulating layer 144.

Referring to FIG. 2, in some embodiments, the semiconductor memory structure 100 further includes a via structure 132 disposed under and coupled to the storage node 118. The via structure 132 is disposed in the insulating layer 144. Further, the via structure 132 helps to provide an electrical connection between the semiconductor memory structure 100 and an underlying metallization layer or an underlying via, though not shown. In some embodiments, the semiconductor memory structure 100 further includes a via structure 134 disposed over and coupled to the conductive layer 130 (i.e., the bit line). The via structure 134 helps to provide an electrical connection between the semiconductor memory structure 100 and an overlying metallization layer 150 (i.e., the metallization layer Mn+1).

Still referring to FIG. 2, as mentioned above, the semiconductor memory structure 100 is disposed in a BEOL interconnect structure. Further, the semiconductor memory structure 100 is disposed in an insulating layer 140 (i.e., an IMD layer, IMDn) of the BEOL interconnect structure. In some embodiments, the insulating layer 140 may include a first region 102, where the semiconductor memory structure 100 is disposed, and a second region 104, where metallization layers 152 and 154 (i.e., the Nth metallization layer Mn and the (N+1)th metallization layer Mn+1) are disposed. Further, a via structure 156 (i.e., the nth via structure Vn) is disposed in the insulating layer 140 in the second region 104 and electrically connects the metallization layers 152 and 154 to each other.

In some embodiments, the semiconductor memory structure 100 is physically separated from the metallization layers 152 and 154 and the via structure 156. In some embodiments, the semiconductor memory structure 100 is electrically separated from the metallization layers 152 and 154 and the via structure 156. In some embodiments, a top surface of the metallization layer 154 is aligned (i.e., coplanar) with a top surface of the metallization layer 150. In some embodiments, a height of the semiconductor memory structure 100 is less than a height of the via structure 156, but the disclosure is not limited thereto.

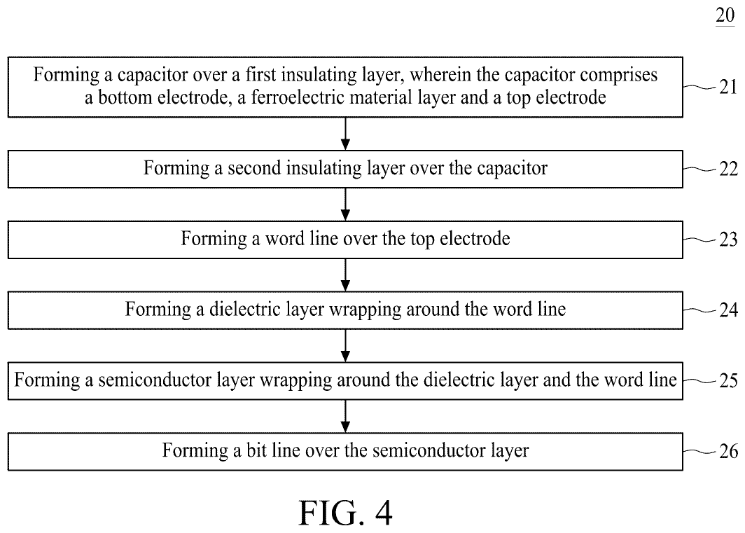

FIG. 4 is a flowchart representing a method for forming a semiconductor memory structure 20 in accordance with aspects of the present disclosure. The method 20 includes a number of operations (21, 22, 23, 24, 25 and 26). The method 20 will be further described according to one or more embodiments. It should be noted that the operations of the method 20 may be rearranged or otherwise modified within the scope of the various aspects. It should be further noted that additional processes may be provided before, during, and after the method 20, and that some other processes may be only briefly described herein. Thus, other implementations are possible within the scope of the various aspects described herein.

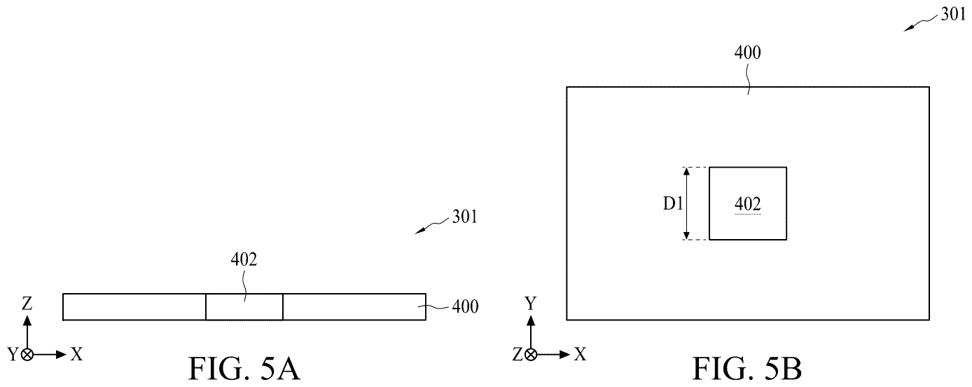

In some embodiments, a semiconductor memory structure 300 may be formed by the method 20. FIGS. 5A to 14A are cross-sectional views of the semiconductor memory structure 300 at various fabrication stages in a first plane (e.g., an X-Z plane), and FIGS. 5B to 14B are cross-sectional views of the semiconductor memory structure 300 at the various fabrication stages in a second plane (e.g., an X-Y plane) in accordance with aspects of one or more embodiments of the present disclosure.

For example, FIGS. 5A and 5B are cross-sectional views of different planes of an intermediate semiconductor structure 301 at a fabrication stage in accordance with aspects of one or more embodiments of the present disclosure. In some embodiments, in operation 21, a capacitor is formed over a first insulating layer. In some embodiments, operation 21 may include further operations. For example, an insulating layer 400 is provided or formed over a substrate (not shown). In some embodiments, the substrate may be similar to that described above; therefore, repeated descriptions of such details are omitted for brevity. In some embodiments, FEOL devices can be formed over the substrate, a MEOL interconnect structure (not shown) can be formed over the substrate, and a BEOL interconnect structure (not shown) is formed over the substrate and electrically connected to the FEOL devices over the substrate through the MEOL interconnect structure. The details of the FEOL devices, the MEOL interconnect structure, and the BEOL interconnect structure may be similar to those described above; therefore, repeated descriptions are omitted for brevity.

Still referring to FIGS. 5A and 5B, in some embodiments, the insulating layer 400 may be a portion of an inter-metal dielectric (IMD) layer of the BEOL interconnect structure. In some embodiments, a via structure 402 may be formed in the insulating layer 400. In some embodiments, a parameter D1 (e.g., a width, a length or a diameter) of the via structure 402 may be between approximately 10 nanometers and approximately 5,000 nanometers, but the disclosure is not limited thereto. In some embodiments, the via structure 402 may be formed by removing a portion of the insulating layer 400 to form an opening (not shown), filling the opening with a conductive material, and removing superfluous portions of the conductive material by a planarization operation such as, for example but not limited thereto, a chemical-mechanical polish (CMP).

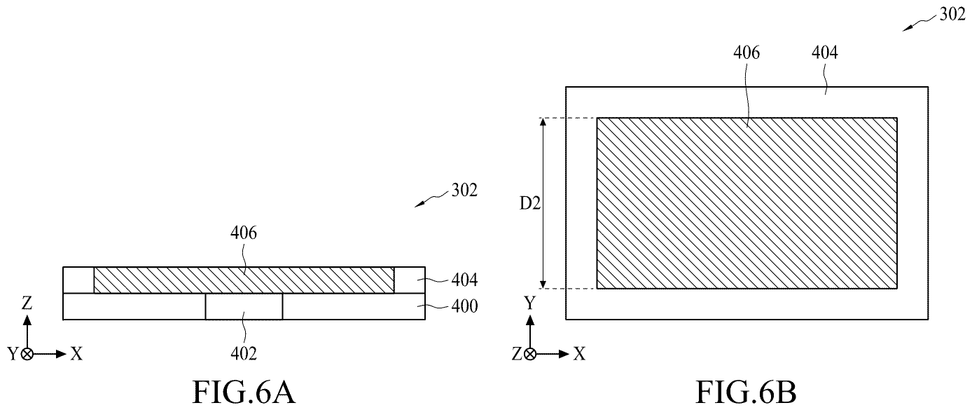

Please refer to FIGS. 6A and 6B, which are cross-sectional views of different planes of an intermediate semiconductor structure 302 at a fabrication stage in accordance with aspects of one or more embodiments of the present disclosure. In some embodiments, the first insulating layer (i.e., the insulating layer 404) may be formed over the insulating layer 400. Further, the insulating layer 404 may include a material same as that of the insulating layer 400. For example but not limited thereto, the insulating layer 400 and the insulating layer 404 may both include silicon oxide. In some embodiments, a storage node 406 may be formed in the insulating layer 404. In some embodiments, a parameter D2 (e.g., a width, a length or a diameter) of the storage node 406 may be between approximately 10 nanometers and approximately 5,000 nanometers, but the disclosure is not limited thereto. In some embodiments, a material of the storage node 406 may be similar to that of the storage node 118 described above; therefore, repeated descriptions are omitted. In some embodiments, the storage node 406 may be formed by removing a portion of the insulating layer 404 to form an opening (not shown), filling the opening with a conductive material, and removing superfluous portions of the conductive material by a planarization operation such as, for example but not limited thereto, a CMP.

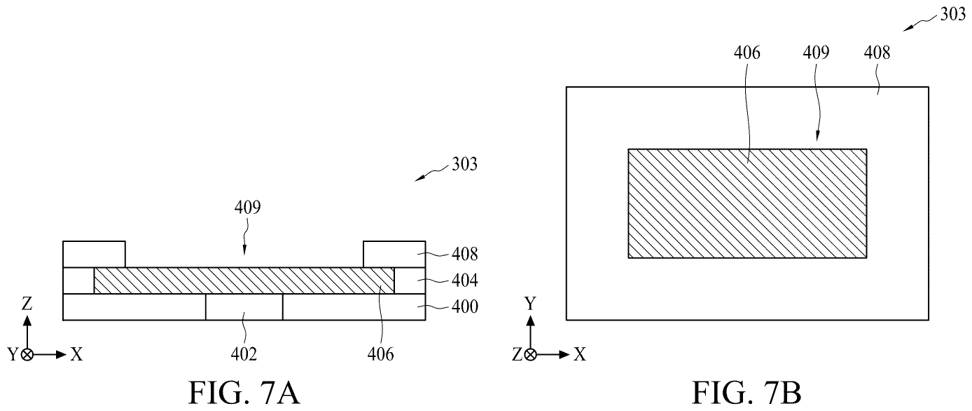

Please refer to FIGS. 7A and 7B, which are cross-sectional views of different planes of an intermediate semiconductor structure 303 at a fabrication stage in accordance with aspects of one or more embodiments of the present disclosure. In some embodiments, a patterned insulating layer 408 may be formed over the insulating layer 404. Further, the patterned insulating layer 408 may include a material different from that of the insulating layer 404. For example but not limited thereto, the patterned insulating layer 408 may include silicon nitride, while the insulating layer 408 includes silicon oxide. In some embodiments, the patterned insulating layer 408 includes an opening 409 exposing a portion of the storage node 406, as shown in FIGS. 7A and 7B. In some embodiments, a dimension of the opening 409 is less than a dimension of the underlying storage node 406, but the disclosure is not limited thereto.

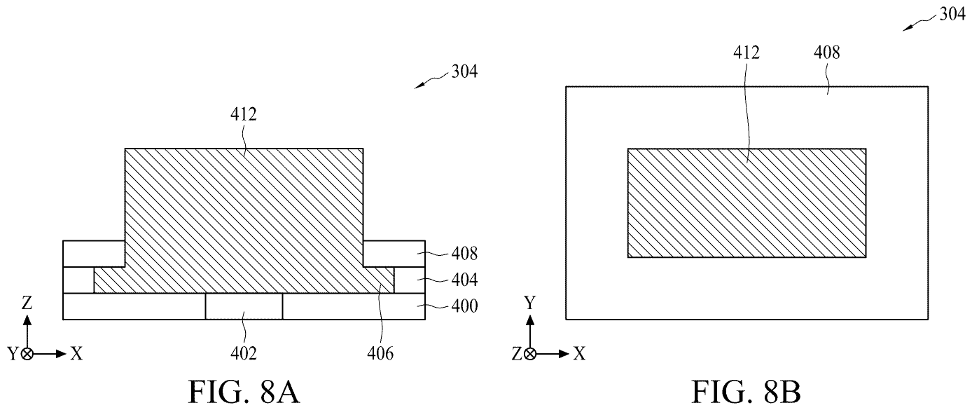

Please refer to FIGS. 8A and 8B, which are cross-sectional views of different planes of an intermediate semiconductor structure 304 at a fabrication stage in accordance with aspects of one or more embodiments of the present disclosure. In some embodiments, a conductive layer may be formed to fill the opening 409 and over the patterned insulating layer 408. Subsequently, a portion of the conductive layer is removed to form a bottom electrode 412 coupled to the storage node 406. In some embodiments, a material of the bottom electrode 412 may similar to that of the bottom electrode 112 described above; therefore, repeated descriptions are omitted for brevity. In some embodiments, the storage node 406 and the bottom electrode 412 may include a same material, but the disclosure is not limited thereto. In some embodiments, a thickness of the bottom electrode 412 is greater than a thickness of the patterned insulating layer 408, but the disclosure is not limited thereto. In some embodiments, a dimension of the bottom electrode 412 is less than a dimension of the storage node 406, but the disclosure is not limited thereto.

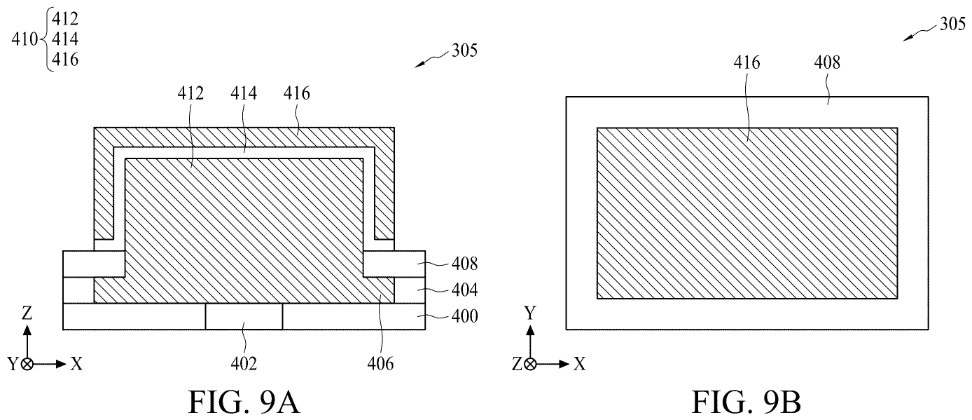

Please refer to FIGS. 9A and 9B, which are cross-sectional views of different planes of an intermediate semiconductor structure 305 at a fabrication stage in accordance with aspects of one or more embodiments of the present disclosure. In some embodiments, a ferroelectric material layer 414 and another conductive layer are sequentially formed over the bottom electrode 412. Further, the ferroelectric material layer 414 and the conductive layer are conformally formed over the bottom electrode 412. In some embodiments, a material of the conductive layer may be same as that of the conductive layer used for forming the bottom electrode 412.

Still referring to FIGS. 9A and 9B, in some embodiments, portions of the ferroelectric material layer 414 and portions of the conductive layer are removed, thereby forming a top electrode 416 over the bottom electrode 412 with the ferroelectric material layer 414 disposed therebetween. Accordingly, a capacitor 410 is formed over the first insulating layer (i.e., the insulating layer 404). As shown in FIG. 9A, the ferroelectric material layer 414 is formed over a top and sidewalls of the bottom electrode 412.

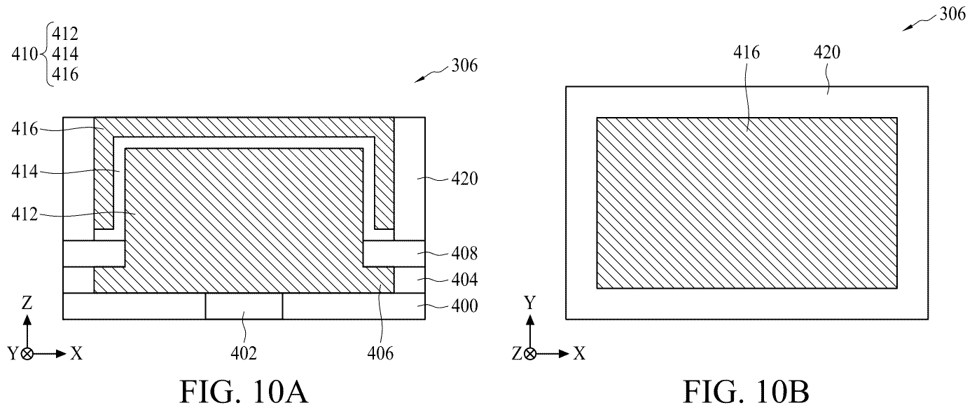

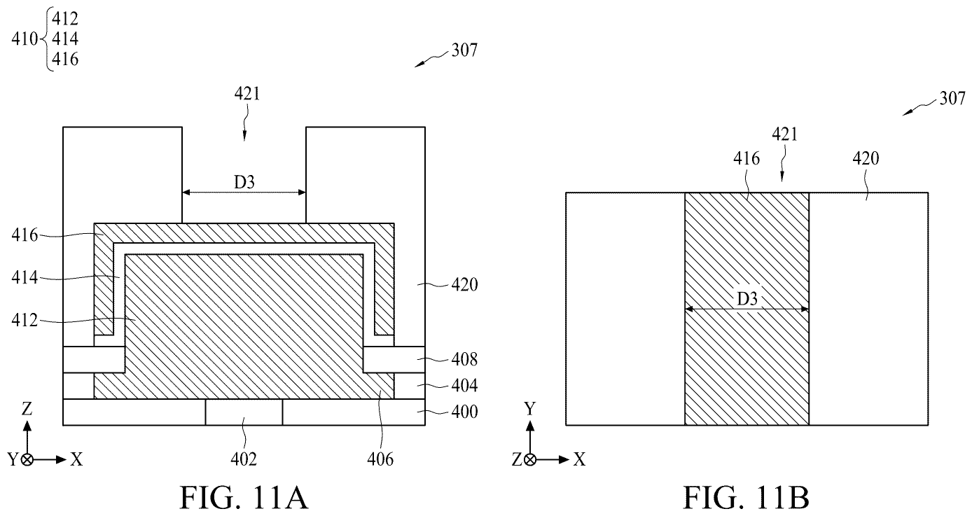

Please refer to FIGS. 10A and 10B, which are cross-sectional views of different planes of an intermediate semiconductor structure 306 at a fabrication stage in accordance with aspects of one or more embodiments of the present disclosure. In some embodiments, in operation 22, a second insulating layer 420 is formed over the capacitor 410. In some embodiments, operation 22 includes further operations. For example, in some embodiments, a planarization such as a CMP may be performed on the second insulating layer 420 such that a top surface of the second insulating layer 420 is aligned (i.e., coplanar) with a top surface of the top electrode 416 of the capacitor 410. In such embodiments, an additional insulating layer may be formed over the second insulating layer 420, as shown in FIGS. 11A and 11B. Further, in such embodiments, the additional insulating layer may include a material same as that of the second insulating layer 420. Therefore, such additional insulating layer may be referred to as a part of the second insulating layer 420, as shown in FIGS. 11A and 11B.

However, in some alternative embodiments, the planarization operation may be omitted. In such embodiments, the second insulating layer 420 is formed over the capacitor 410. Further, the second insulating layer 420 may entirely cover the capacitor 410.

In some embodiments, in operation 23, a word line is formed over the capacitor 410. In some embodiments, operation 23 includes further operations. For example, as shown in FIGS. 11A and 11B, which are cross-sectional views of different planes of an intermediate semiconductor structure 307 at a fabrication stage in accordance with aspects of one or more embodiments of the present disclosure, an opening 421 is formed in the second insulating layer 420. In some embodiments, the opening 421 may include a strip configuration that extends in the Y direction. In some embodiments, a parameter D3 of the opening 421 may be between approximately 0.3 nanometers and approximately 150 nanometers, but the disclosure is not limited thereto. In some embodiments, the parameter D3 may be a width of the opening 421 that is measured along the X direction. Further, a portion of the top electrode 416 is exposed through the opening 421.

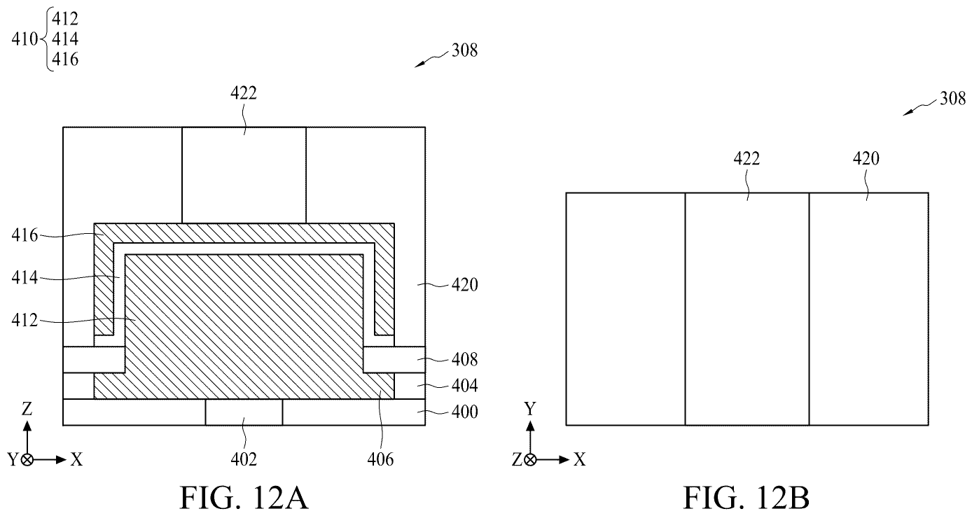

Please refer to FIGS. 12A and 12B, which are cross-sectional views of different planes of an intermediate semiconductor structure 308 at a fabrication stage in accordance with aspects of one or more embodiments of the present disclosure. In some embodiments, a sacrificial layer 422 is formed to fill the opening 421. In some embodiments, the sacrificial layer 422 includes a material different from that of the second insulating layer 420. For example but not limited thereto, the sacrificial layer 422 may include silicon nitride, while the second insulating layer 420 includes silicon oxide. In some embodiments, the sacrificial layer 422 may be formed to fill the opening 421 and further cover the second insulating layer 420, and a planarization operation is performed to remove superfluous portions of the sacrificial layer 422. Accordingly, a top surface of the sacrificial layer 422 may be aligned (i.e., coplanar) with a top surface of the second insulating layer 420.

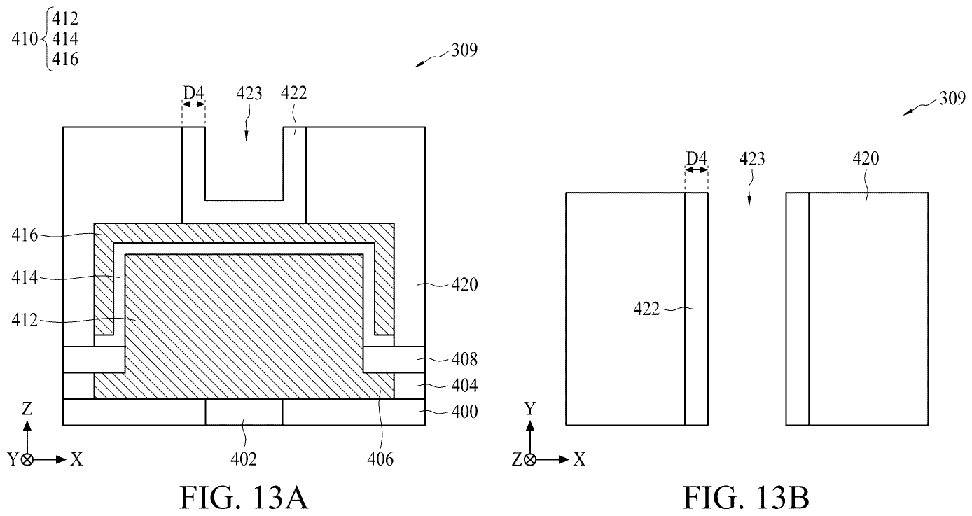

Please refer to FIGS. 13A and 13B, which are cross-sectional views of different planes of an intermediate semiconductor structure 309 at a fabrication stage in accordance with aspects of one or more embodiments of the present disclosure. In some embodiments, a portion of the sacrificial layer 422 is removed to form an opening 423. In some embodiments, the sacrificial layer 422 may include a U-shaped configuration in the X-Z plane, as shown in FIG. 13A. In some embodiments, a parameter D4 of a topmost portion of the U-shaped sacrificial layer 422 is between approximately 0.1 nanometers and approximately 10 nanometers, but the disclosure is not limited thereto. In some embodiments, the parameter D4 is a width measured in the X direction.

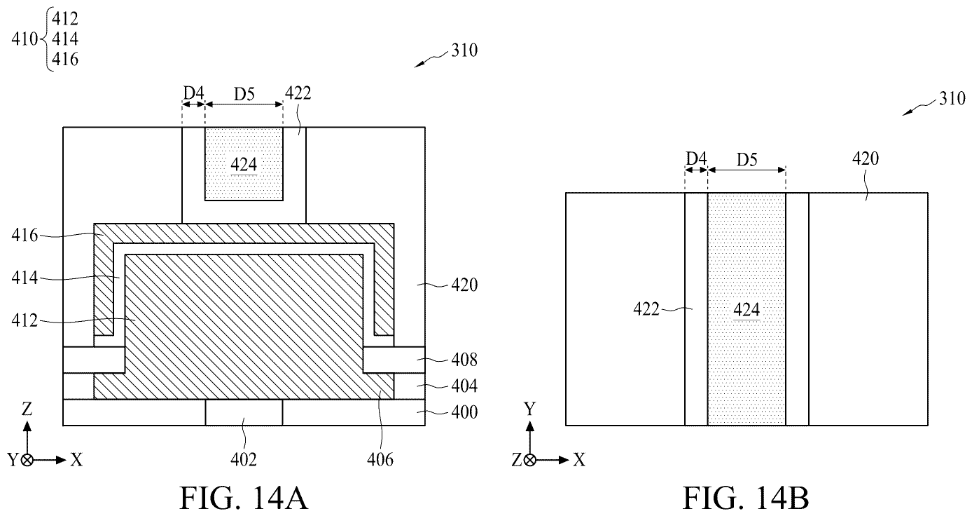

Please refer to FIGS. 14A and 14B, which are cross-sectional views of different planes of an intermediate semiconductor structure 310 at a fabrication stage in accordance with aspects of one or more embodiments of the present disclosure. In some embodiments, a conductive layer is formed to fill the opening 423. In some embodiments, a planarization operation may be performed to remove superfluous portions of the conductive layer, thereby forming a word line 424 over the sacrificial layer 422, as shown in FIG. 14A. Further, portions of the sacrificial layer 422 are exposed, and the top surface of the sacrificial layer 422, the top surface of the second insulating layer 420 and a top surface of the word line 424 may be aligned (i.e., coplanar) with each other. In some embodiments, a parameter D5 of the word line 424 may be between approximately 0.1 nanometers and approximately 100 nanometers, but the disclosure is not limited thereto. In some embodiments, the parameter D5 may be a width of the word line 424 that is measured along the X direction.

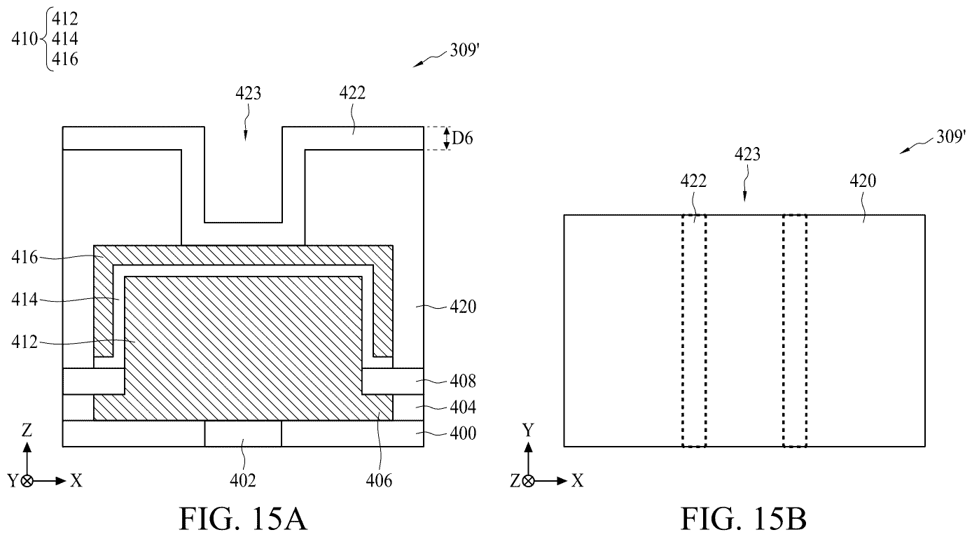

Please refer to FIGS. 15A and 15B, which are cross-sectional views of different planes of an intermediate semiconductor structure 309′ at a fabrication stage subsequent to that shown in FIGS. 11A and 11B. In some embodiments, after the forming of the opening 421, a sacrificial layer 422 is conformally formed in the opening 421. In such embodiments, a bottom and sidewalls of the opening 421 are covered by the sacrificial layer 422. In some embodiments, a parameter D6 of the sacrificial layer 422 is between approximately 0.1 nanometers and approximately 10 nanometers, but the disclosure is not limited thereto. In some embodiments, the parameter D6 of the sacrificial layer 422 is a thickness of the sacrificial layer 422 that measures along the Z direction.

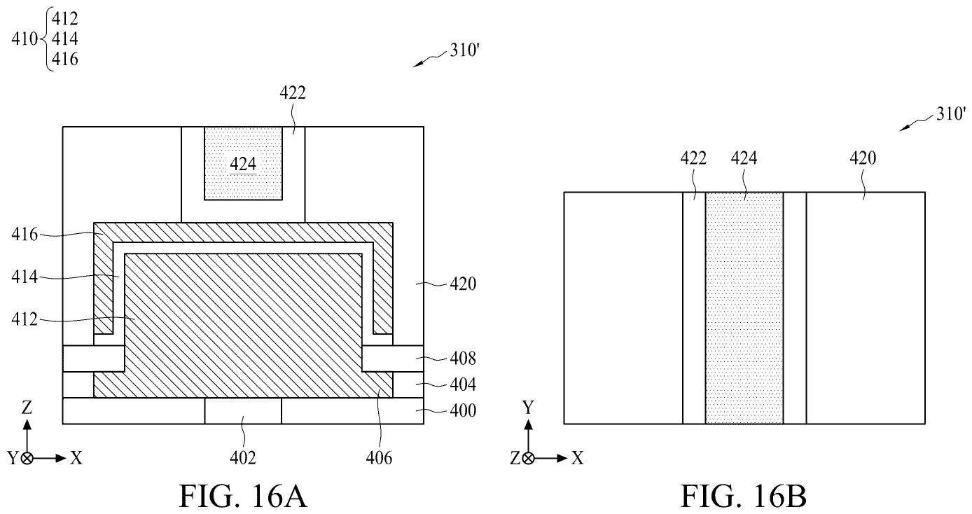

Please refer to FIGS. 16A and 16B, which are cross-sectional views of different planes of an intermediate semiconductor structure 310′ at a fabrication stage in accordance with aspects of one or more embodiments of the present disclosure. In some embodiments, a conductive layer is formed to fill the opening 423. In some embodiments, a planarization operation may be performed to remove superfluous portions of the conductive layer, thereby forming a word line 424 over the sacrificial layer 422, as shown in FIG. 16A. Further, portions of the sacrificial layer 422 are exposed, and the top surface of the sacrificial layer 422, the top surface of the second insulating layer 420 and a top surface of the word line 424 may be aligned (i.e., coplanar) with each other.

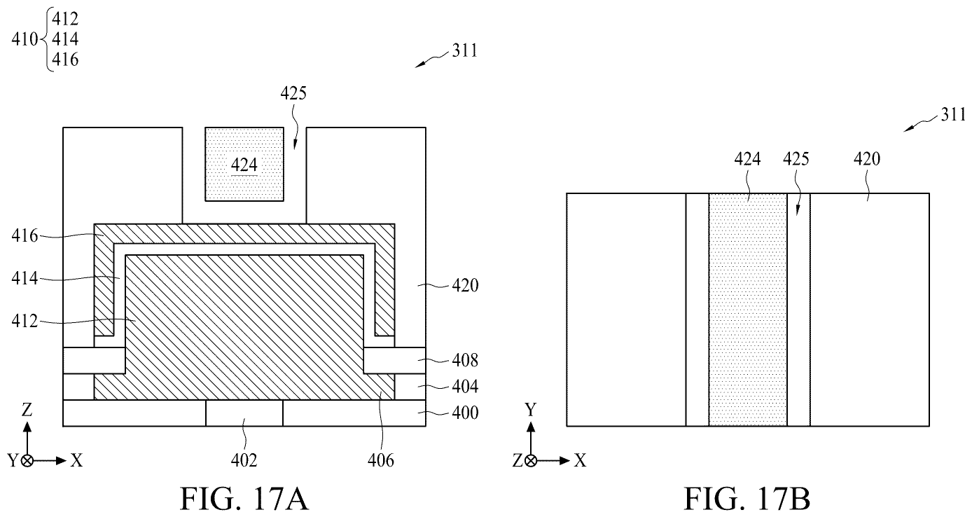

In some embodiments, in operation 24, a dielectric layer is formed to wrap around the word line 424. In some embodiments, operation 24 includes further operations. For example, as shown in FIGS. 17A and 17B, which are cross-sectional views of different planes of an intermediate semiconductor structure 311 at a fabrication stage subsequent to that shown in FIGS. 14A and 14B or in FIGS. 16A and 16B in accordance with aspects of one or more embodiments of the present disclosure, the sacrificial layer 422 is removed. An air gap 425 is formed after the removing of the sacrificial layer 422. In some embodiments, it can be said that the word line 424 is suspended over and exposed through the air gap 425.

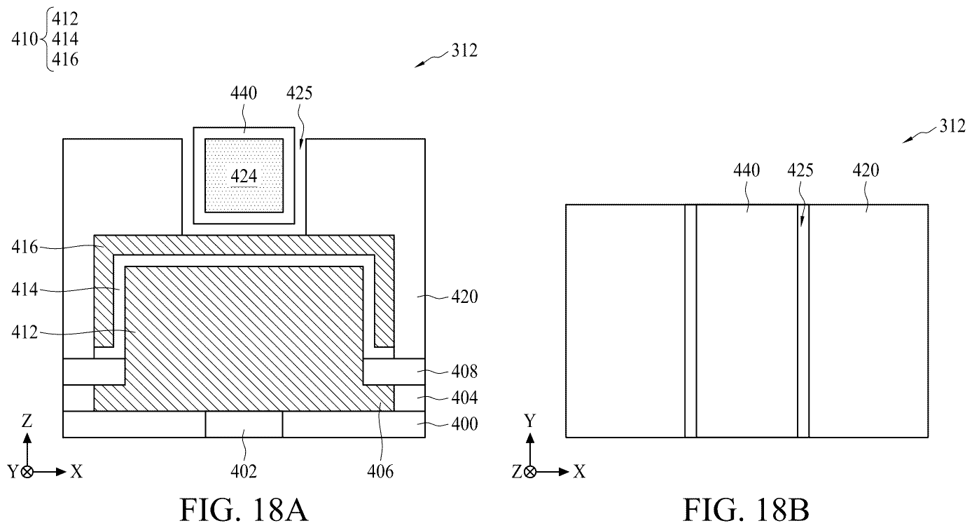

Please refer to FIGS. 18A and 18B, which are cross-sectional views of different planes of an intermediate semiconductor structure 312 at a fabrication stage in accordance with aspects of one or more embodiments of the present disclosure. In some embodiments, a dielectric layer 440 is formed in to wrap around the word line 424. In some embodiments, the dielectric layer 440 may be formed by an atomic layer deposition (ALD), thereby forming the dielectric layer 440 over surfaces of the word line 424 that are exposed through the air gap 425. In some embodiments, a material of the dielectric layer 440 may be similar to that of the dielectric layer 126 mentioned above; therefore, repeated descriptions are omitted for brevity.

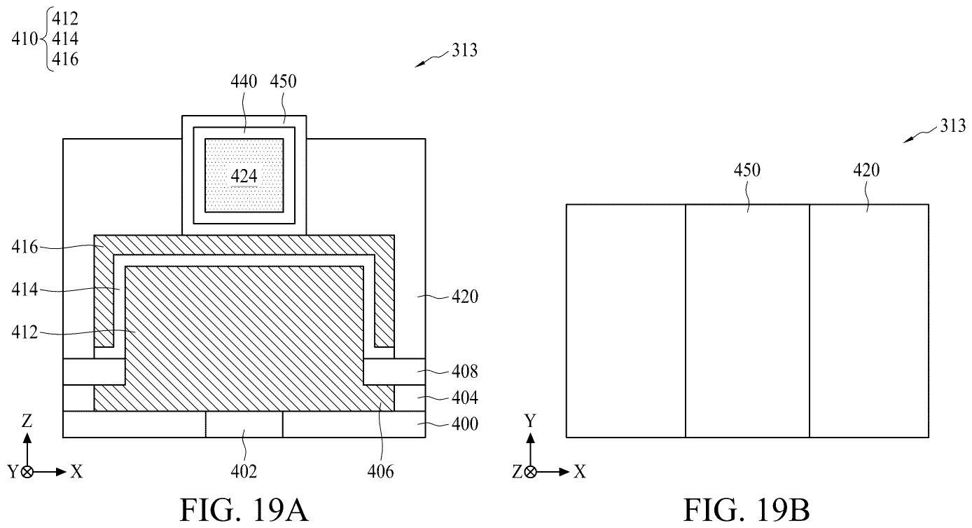

Please refer to FIGS. 19A and 19B, which are cross-sectional views of different planes of an intermediate semiconductor structure 313 at a fabrication stage in accordance with aspects of one or more embodiments of the present disclosure. In some embodiments, in operation 25, a semiconductor layer 450 is formed to wrap around the dielectric layer 440 and the word line 424. In some embodiments, the semiconductor layer 450 may be formed by an ALD, thereby forming the semiconductor layer 450 over surfaces of the dielectric layer 440 that are exposed through the air gap 425. Further, the air gap 425 is filled with the semiconductor layer 450. In some embodiments, the semiconductor layer 450 may be an oxide semiconductor layer. In such embodiments, the oxide semiconductor layer may include a material similar to that of the semiconductor layer 124 described above; therefore, repeated descriptions are omitted for brevity.

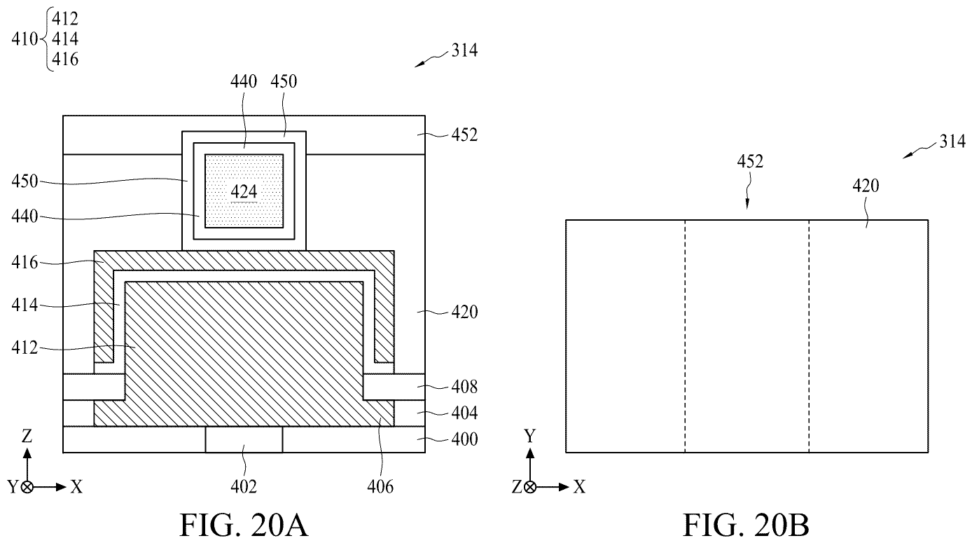

Please refer to FIGS. 20A and 20B, which are cross-sectional views of different planes of an intermediate semiconductor structure 314 at a fabrication stage in accordance with aspects of one or more embodiments of the present disclosure. In some embodiments, in operation 26, a bit line is formed over the semiconductor layer 450. In some embodiments, operation 26 includes further operations. For example, a third insulating layer 452 may be formed over the semiconductor layer 450. In some embodiments, the third insulating layer 452 includes a material same as that of the second insulating layer 420, but the disclosure is not limited thereto. In some embodiments, the third insulating layer 452 is formed to cover the semiconductor layer 450, as shown in FIGS. 20A and 20B.

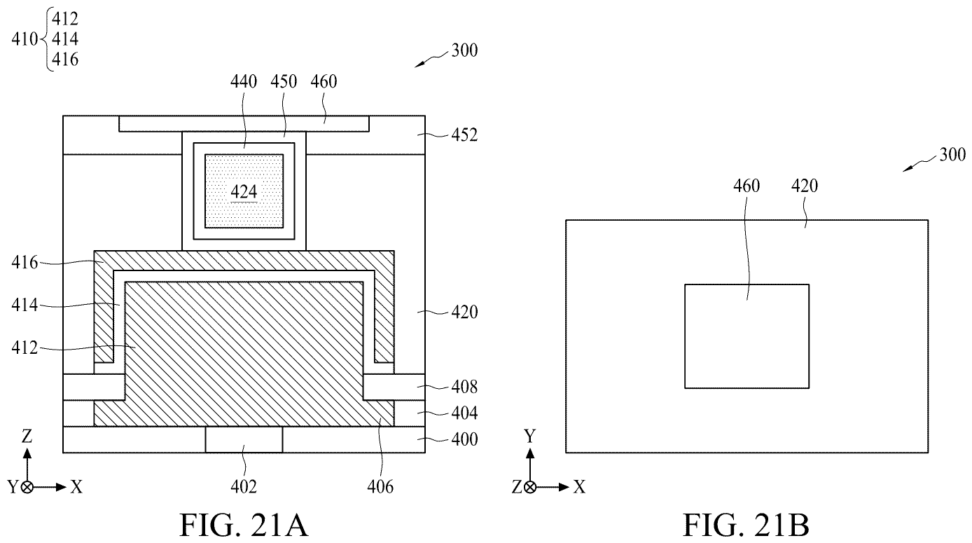

Please refer to FIGS. 21A and 21B, which are cross-sectional views of different planes of a semiconductor structure 300 at a fabrication stage in accordance with aspects of one or more embodiments of the present disclosure. A portion of the third insulating layer 452 is removed to form an opening (not shown) exposing a portion of the semiconductor layer 450. Subsequently, a conductive layer is formed to fill the opening, and a planarization operation is performed to remove superfluous portions of the conductive layer, thereby forming the bit line 460, as shown in FIGS. 21A and 21B. Accordingly, the semiconductor memory structure 300 is formed.

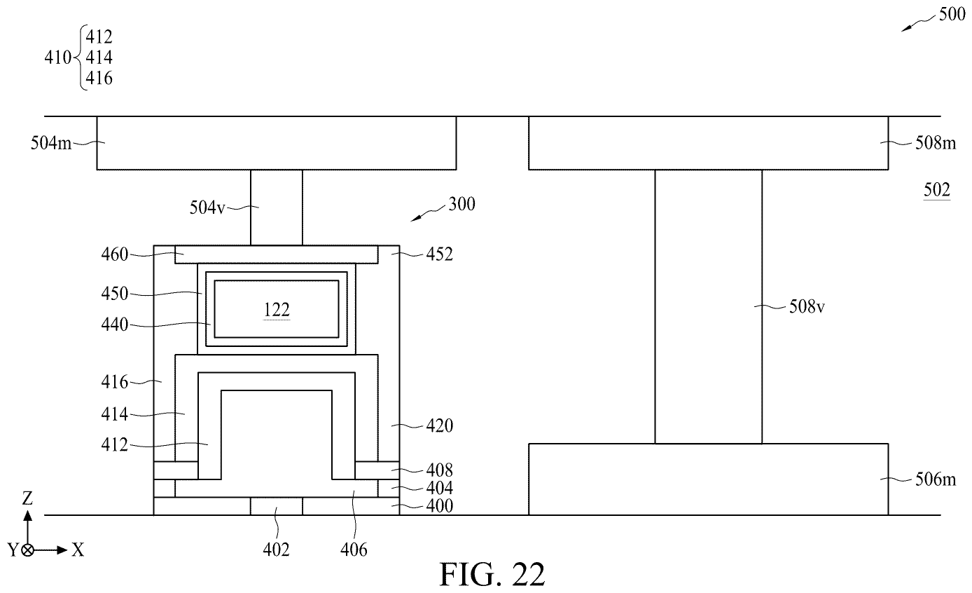

Please refer to FIG. 22, which is a cross-sectional view illustrating a semiconductor structure 500 in accordance with aspects of one or more embodiments of the present disclosure. In some embodiments, the semiconductor memory structure 300 is formed in a BEOL interconnect structure. In such embodiments, an IMD layer 502 is formed, and a metallization layer 504m and a via structure 504v are formed in the IMD layer 502. Further, the via structure 504v is coupled to the bit line 460 of the semiconductor memory structure 300. In some embodiments, the semiconductor memory structure 300 is electrically connected to the metallization layer 504m through the via structure 504v.

Still referring to FIG. 22, in some embodiments, more metallization layers and via structures can be formed in the IMD layer 502. For example, a metallization layer 506m may be formed in the IMD layer 502. Further, a metallization layer 508m and a via structure 508v may be formed to electrically connect to the metallization layer 506m. In some embodiments, the formation of the metallization layer 506m, the via structure 508v and the metallization layer 508m may be performed prior to the formation of the semiconductor memory structure 300. In some alternative embodiments, the formation of the metallization layer 506m, the via structure 508v and the metallization layer 508m may be performed after the formation of the semiconductor memory structure 300. In some embodiments, the formation of the metallization layers 504m, 506m, 508, and the via structures 504v, 508v can include forming trenches and via openings in the IMD layer 502, filling the trench and the via openings with conductive materials, and performing a planarization such as a CMP operation. Further, in some embodiments, the metallization layer 506m, the via structure 508v and the metallization layer 508m are separated from the semiconductor memory structure 300.

Accordingly, the present disclosure provides a semiconductor memory structure and a method for forming the same. In some embodiments, the semiconductor memory structure is a non-planar 1T1C FeRAM formed in a BEOL interconnect structure. The 1T1C FeRAM helps to provide lower operation noise of an unselected bit line BL and better data retention. The non-planar 1T1C FeRAM is 3D stackable; therefore, it helps to increase device density. The non-planar 1T1C FeRAM integrated in the BEOL interconnect structure is a BEOL junction-less device. Further, the method for forming the non-planar 1T1C FeRAM integrated in the BEOL interconnect structure is a logic-compatible process.

In accordance with some embodiments, a semiconductor device is provided. The semiconductor device includes a capacitor and a transistor disposed over and coupled to the capacitor. The capacitor includes a bottom electrode, a top electrode, and a ferroelectric material layer between the bottom electrode and the top electrode. The ferroelectric material layer covers sidewalls and a top surface of the bottom electrode. The transistor is coupled to the top electrode of the capacitor. The transistor includes a gate, a semiconductor layer wrapped around the gate, and a dielectric layer between the gate and the semiconductor layer.

In some embodiments, a semiconductor structure is provided. The semiconductor structure includes an insulating layer including a first region and a second region, a memory structure and a first metallization layer disposed in the insulating layer in the first region, and a second metallization layer disposed in the insulating layer in the second region. The second metallization layer is separated from the first metallization layer. A top surface of the second metallization layer is aligned with a top surface of the first metallization layer.

In some embodiments, a method for forming a semiconductor memory structure is provided. The method includes following operations. A capacitor is formed over a first insulating layer. The capacitor includes a bottom electrode, a ferroelectric material layer over a top and sidewalls of the bottom electrode, and a top electrode over the ferroelectric material layer. A second insulating layer is formed over the capacitor. A word line is formed over the capacitor. A dielectric is formed to wrap around the word line. A semiconductor layer is formed to wrap around the dielectric layer and the word line. A bit line is formed over the semiconductor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a capacitor comprising:
a bottom electrode;
a top electrode; and
a ferroelectric material layer between the bottom electrode and the top electrode, wherein the ferroelectric material layer covers sidewall and a top surface of the bottom electrode; and
a transistor disposed over and coupled to the top electrode of the capacitor, wherein the transistor comprises:
a gate;
a semiconductor layer wrapped around the gate; and
a dielectric layer between the semiconductor layer and the gate.

2. The semiconductor device of claim 1, further comprising a storage node disposed under and coupled to the bottom electrode.

3. The semiconductor device of claim 2, further comprising a via structure disposed under and coupled to the storage node.

4. The semiconductor device of claim 1, further comprising a bit line disposed over and coupled to a top of the semiconductor layer of the transistor.

5. The semiconductor device of claim 1, wherein the semiconductor layer comprises an oxide semiconductor material.

6. The semiconductor device of claim 1, wherein each of the semiconductor layer and the dielectric layer has an O-shaped configuration in a cross-sectional view.

7. A semiconductor structure comprising:
an insulating layer comprising a first region and a second region;
a memory structure disposed in the insulating layer in the first region, wherein the memory structure comprises:
a capacitor;
a word line disposed over the capacitor;
an oxide semiconductor layer disposed between the word line and the capacitor; and
a dielectric layer disposed between the word line and the oxide semiconductor layer;
a conductive layer disposed over and coupled to a top of the oxide semiconductor layer of the memory cell in the first region;
a first metallization layer disposed in the insulating layer in the first region; and
a second metallization layer disposed in the insulating layer in the second region, wherein the second metallization layer is separated from the first metallization layer, and a top surface of the second metallization layer is aligned with a top surface of the first metallization layer.

8. The semiconductor structure of claim 7, further comprising a first via structure electrically connecting the conductive layer to the first metallization layer.

9. The semiconductor structure of claim 7, further comprising:
a third metallization layer under the second metallization layer in the second region; and
a second via structure in the insulating layer and electrically connecting the third metallization layer to the second metallization layer.

10. The semiconductor structure of claim 9, wherein a height of the memory cell is less than a height of the second via structure.

11. The semiconductor structure of claim 7, wherein the capacitor of the memory cell comprises:
a bottom electrode;
a top electrode; and
a ferroelectric material layer between the bottom electrode and the top electrode,
wherein the ferroelectric material layer covers a top surface and sidewalls of the bottom electrode.

12. The semiconductor structure of claim 7, wherein each of the oxide semiconductor layer and the dielectric layer has an O-shaped configuration in a cross-sectional view.

13. A method for forming a semiconductor memory structure, comprising:
forming a capacitor over a first insulating layer, wherein the capacitor comprises a bottom electrode, a ferroelectric material layer over a top and sidewalls of the bottom electrode, and a top electrode over the ferroelectric material layer;
forming a second insulating layer over the capacitor;
forming a word line over the capacitor;
forming a dielectric layer wrapped around the word line;
forming a semiconductor layer wrapped around the dielectric layer and the word line; and
forming a bit line over the semiconductor layer.

14. The method of claim 13, wherein the forming of the capacitor further comprises:
forming a patterned insulating layer over the first insulating layer;
forming a conductive layer over the patterned insulating layer; and
removing a portion of the conductive layer to form the bottom electrode.

15. The method of claim 13, wherein the forming of the word line further comprises:
forming a first opening in the second insulating layer;
forming a sacrificial layer in the first opening;
forming the word line over the sacrificial layer; and
removing the sacrificial layer.

16. The method of claim 15, wherein an air gap is formed after the removing of the sacrificial layer, and the dielectric layer and the semiconductor layer fill the air gap.

17. The method of claim 15, wherein the forming of the sacrificial layer further comprises:
filling the first opening with the sacrificial layer; and
removing a portion of the sacrificial layer to form a second opening,
wherein the second opening is filled with the word line.

18. The method of claim 15, wherein the forming of the sacrificial layer further comprises:
conformally forming the sacrificial layer in the first opening to form a second opening,
wherein the second opening is filled with the word line.

19. The method of claim 13, further comprising forming a third insulating layer over the semiconductor layer, wherein the bit line is formed in the third insulating layer.

20. The method of claim 13, further comprising forming a metallization layer and a via structure coupled to the metallization layer in the first insulating layer, wherein the metallization layer and the via structure are separated from the bottom electrode, the top electrode and the word line.
